(19) United States
(12) Patent Application Publication
(10) Pub. No.: US 2006/0276050 A1
(43) Pub. Date: Dec. 7, 2006

(54) Method for manufacturing crystalline dielectric film,crystalline dielectric film manufactured thereby and thin film capacitor having the same

(75) Inventors: Won Hoon Song, Seoul (KR); Yul Kyo Chung, Yongin (KR); Hyoung Dong Kang, Yongin (KR); Sung Taek Lim, Incheon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/445,232

(22) Filed: Jun. 2, 2006

(30) Foreign Application Priority Data
Jun. 3, 2005 (KR) 10-2005-0047997

(51) Int. Cl. H01L 21/31; H01L 21/469

(52) U.S. Cl. 438/758

(57) ABSTRACT

The invention provides a method for manufacturing a crystalline dielectric film by which the crystalline dielectric film can be formed at a low temperature of 300° C. or less. In the manufacturing method of the invention, first, an amorphous dielectric film is formed on a substrate. Then, the amorphous dielectric film is immersed into water to be hydrothermally treated.

### CLAIM OF PRIORITY

This application claims the benefit of Korean Patent Application No. 2005-0047997 filed on Jun. 3, 2005 in the Korean Intellectual Property Office, the disclosure of which is incorporated herein by reference.

### BACKGROUND OF THE INVENTION

1. Field of the Invention

The present invention relates to a method for manufacturing a dielectric film for use in a capacitor. More particularly, the present invention relates to a method for manufacturing a crystalline dielectric film capable of crystallizing the dielectric film at a low temperature of 300° C. or less, a dielectric film manufactured thereby and a thin film capacitor having the same.

2. Description of the Related Art

Recently, with an increasing tendency of miniaturization and higher-frequency in a printed circuit board, passive devices mounted on the printed circuit board have served as a stumbling block to miniaturization of products. Especially, rapid spread of embedded semiconductor devices and increase in the number of input/output terminals have led to smaller spaces for arranging many passive devices including a capacitor around an active integrated circuit chip. Also, a decoupling capacitor is used to provide electric source to the input terminal stably. Such decoupling capacitor should be positioned in closest proximity to the input terminal to reduce inductance caused by a high frequency.

With a rising demand for smaller electronic devices and higher-frequency properties, a method for optimally disposing a capacitor around an active integrated circuit chip has been proposed. For this purpose, a capacitor is embedded into a substrate beneath the integrated circuit chip. Especially, a thin film embedded capacitor is characterized by forming a dielectric film inside the printed circuit board beneath the active integrated circuit chip. The thin film embedded capacitor is disposed in very close proximity to the input terminal of the active integrated circuit chip, thereby shortening the length of a lead wire connecting the integrated circuit chip terminal and capacitor. This effectively decreases inductance caused by a high frequency.

To obtain sufficient capacitance from the thin film embedded capacitor requires a high dielectric constant of the dielectric film used for the capacitor. Dielectric material inside the film should be crystalline to obtain a high dielectric constant. To produce the crystalline dielectric film, typically, an amorphous dielectric film is formed on a substrate and then crystallized via thermal treatment. That is, an amorphous dielectric film, which is not sufficient for a capacitor material, needs to be thermally treated to crystallize the amorphous film.

FIG. 1 is a schematic flowchart illustrating a method for manufacturing a crystalline dielectric film according to the prior art. Referring to FIG. 1, a dielectric sol such as a TiO₂ sol or a PLZT sol is prepared in advance and then coated onto a substrate in step R1. Next, the dielectric sol coated is pyrolyzed at a temperature of 300° C. to 400° C. to remove organic substance from the sol in step R2. This allows an amorphous dielectric film to be formed on the substrate. Thereafter, the dielectric film formed on the substrate is thermally treated or fired at a temperature of 600° C. to be crystallized. As a result, this produces a crystalline dielectric film. Japanese Patent No. 2517874 discloses that a titanium dioxide sol is coated onto a substrate and thermally treated at a temperature of 600° C. to 700° C. to make a crystalline TiO₂ film.

However, this method involves thermal treatment at a high temperature of 600° C. or more, thus limiting substrate materials used. That is, this method is hardly applicable to a heat-vulnerable polymer-based printed circuit board. In addition, even in case of using a substrate other than the polymer-based substrate, e.g., a ceramic substrate, thermal impact from a high temperature may impair the substrate or a metal layer formed thereon. Moreover, such thermal treatment leads to increase in process costs and time.

### SUMMARY OF THE INVENTION

The present invention has been made to solve the foregoing problems of the prior art and therefore an object according to an aspect of the present invention is to provide a method for manufacturing a crystalline dielectric film capable of forming the crystalline dielectric film at a low temperature even without a high-temperature process and a crystalline dielectric film manufactured thereby.

An object according to another aspect of the invention is to provide a thin film capacitor having the crystalline dielectric film formed therein according to the aforesaid method.

According to an aspect of the invention for realizing the object, there is provided a method for manufacturing a crystalline dielectric film comprising steps of:

forming an amorphous dielectric film on a substrate; and

hydrothermally treating the amorphous dielectric film by immersing into water.

The hydrothermal treating step comprises heating the amorphous dielectric film at a temperature of 300° C. or less in distilled water within a sealed space.

Preferably, the hydrothermal treating step is carried out at a temperature of 80° C. to 300° C. More preferably, the hydrothermal treating step is carried out at a temperature of 150° C. to 300° C.

According to one embodiment of the invention, the amorphous dielectric film forming step comprises coating the amorphous dielectric sol onto a substrate and baking the coated amorphous dielectric sol. The method may further comprise drying the baked resultant after the baking step. The coating step is carried out by spin coating, deep coating or spray coating.

To obtain a desired thickness of the film, the coating and baking are repeated for a number of times.

According to another embodiment of the invention, the amorphous dielectric film forming step comprises depositing the amorphous dielectric film on the substrate. For example, the amorphous dielectric film depositing step comprises sputtering the amorphous dielectric film onto the substrate.

According to further another embodiment of the invention, the amorphous dielectric film forming step comprises forming an amorphous TiO₂ thin film on the substrate. The amorphous TiO₂ film forming step comprises coating the amorphous TiO₂ sol onto the substrate and baking the coated amorphous TiO₂ sol. At this time, the method may further comprise drying the baked resultant, after the baking step. Preferably, the baking step is carried out at a temperature of 150° C. to 250° C. Preferably, the drying step is carried out at a temperature of 150° C. to 250° C. Alternatively, the amorphous TiO₂ film forming step comprises depositing the amorphous TiO₂ thin film on the substrate via e.g., sputtering.

Preferably, the hydrothermal treating step is carried out at a temperature of 150° C. to 250° C.

According to further another embodiment of the invention, the amorphous dielectric film forming step comprises forming an amorphous PLZT thin film on the substrate. The amorphous PLZT film forming step comprises coating a PLZT sol onto the substrate and baking the coated amorphous PLZT sol. At this time, the method further comprises drying the baked resultant after the baking step. Preferably, the baking step is carried out at a temperature of 150° C. to 250° C. Preferably, the drying step is carried out at a temperature of 150° C. to 250° C. Alternatively, the amorphous PLZT film forming step comprises depositing the amorphous PLZT film on the substrate. Preferably, in forming the PLZT film, the hydrothermal treatment is carried out at a temperature of 200 to 300° C.

According to another aspect of the invention for realizing the object, there is provided a crystalline dielectric film formed by the aforesaid manufacturing method. According to further another aspect of the invention for realizing the object, there is provided a thin film capacitor having a crystalline dielectric film manufactured by the aforesaid method. The thin film capacitor of the invention comprises: a lower electrode; an upper electrode; and a crystalline dielectric film inserted therebetween. The thin film capacitor can be beneficially used as a thin film embedded capacitor.

According to an aspect of the invention, the amorphous dielectric film is crystalizable by conducting a process at a low temperature of 300° C. or less unlike the prior art method. This allows the substrate to be free from damages caused during a high-temperature process, and ensures wider selection for substrate materials. Therefore, a heat-vulnerable polymer-based substrate can be adopted to realize a thin film embedded capacitor. In addition, a relatively simpler process involving no high-temperature process leads to decline in process costs and time.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic flowchart illustrating a method for manufacturing a crystalline dielectric film according to the prior art;

FIG. 2 is a schematic flowchart illustrating a method for manufacturing a crystalline dielectric film according to the invention;

FIGS. 3 to 6 are cross-sectional views for explaining a method for manufacturing a thin film capacitor according to an embodiment of the invention;

FIG. 7a is an SEM picture illustrating a surface of a TiO₂ film before hydrothermal treatment in a manufacturing process according to an embodiment of the invention;

FIG. 7b is an SEM picture illustrating a cross-section of the TiO₂ film of FIG. 7a;

FIG. 8a is an SEM picture illustrating a surface of TiO₂ film hydrothermally treated according to an example of the invention;

FIG. 8b is an SEM picture illustrating a cross-section of the TiO₂ film of FIG. 8a;

FIG. 9 is a graph illustrating capacitance of a thin film capacitor using a crystalline TiO₂ film manufactured according to another example of the invention;

FIG. 10 is a schematic cross-sectional view illustrating a hydrothermal treatment apparatus usable in a manufacturing process of the invention;

FIG. 11a is an SEM picture illustrating a surface of a PLZT thin film hydrothermally treated according to an embodiment of the invention; and

FIG. 11b is an SEM picture illustrating a cross-section of the PLZT thin film of FIG. 11a.

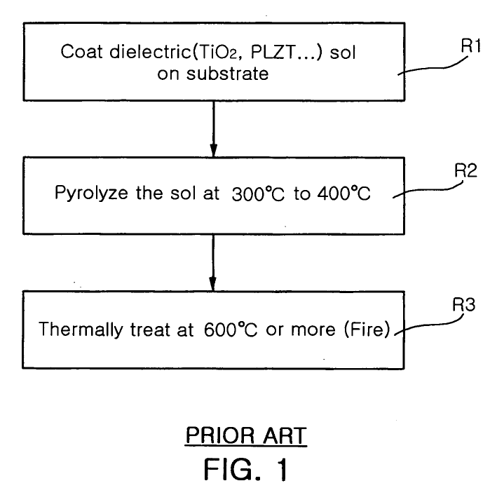

### DETAILED DESCRIPTION OF THE PREFERRED EMBODIMENT

The present invention now will be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference signals are used to designate the same or similar components throughout.

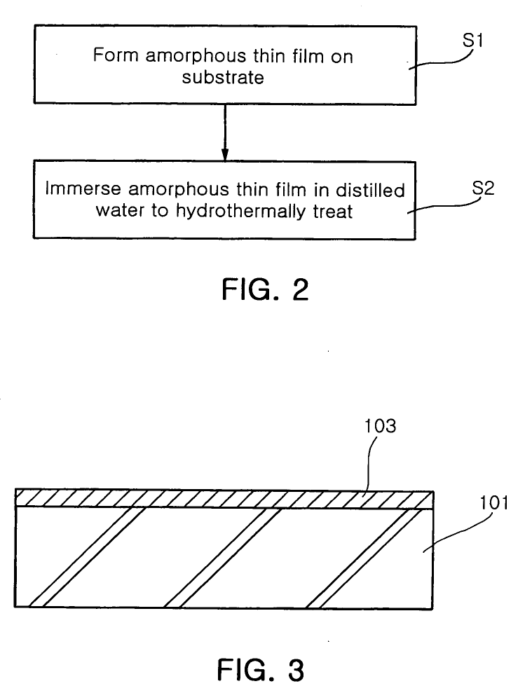

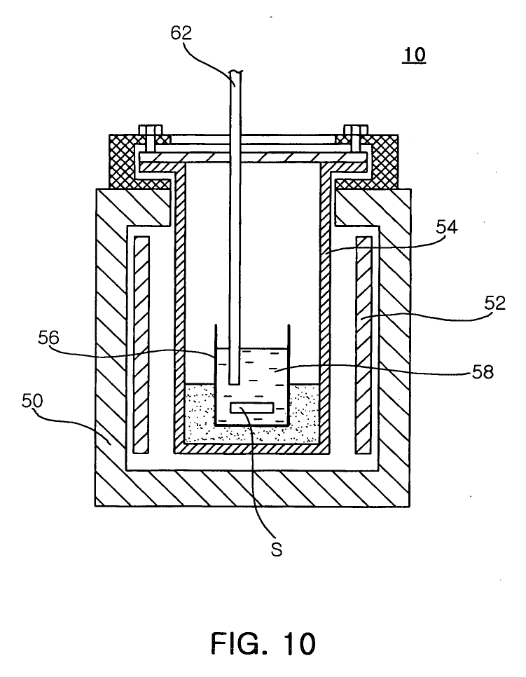

FIG. 2 is a flowchart illustrating a method for manufacturing a crystalline dielectric film according to the invention. Referring to FIG. 2, first, an amorphous dielectric film made of e.g., TiO₂ or PLZT is formed on a substrate in step S1. Then, the substrate having the amorphous crystalline dielectric film formed thereon is hydrothermally treated by a hydrothermal treatment apparatus with distilled water therein (see FIG. 10). Hydrothermal treatment may be carried out at a temperature of 80° C. to 300° C. Herein, hydrothermal treatment denotes heating a workpiece immersed into water within a sealed space. In case of hydrothermal treatment, the workpiece is under not only a thermal energy but also a vapor-induced pressure.

The substrate used is not specifically limited. Due to absence of a high-temperature process, a polymer-based substrate such as epoxy may be employed. The substrate may have a layer of different material such as a lower electrode of a capacitor, formed in an upper part thereof. Also, a silicon (Si) wafer or a metal foil may be used. Especially, a crystalline dielectric film is formed on the metal foil so that a multilayer structure of metal/dielectrics can be directly bonded to the printed circuit board. The metal/dielectrics multilayer structure bonded to the printed circuit board is advantageously employed as a thin film embedded capacitor.

The dielectrics formed on the substrate are exemplified by TiO₂ and PLZT. These dielectrics, if crystallized, exhibit a sufficient dielectric constant to be used for a thin film capacitor. However, the invention is not limited to the two dielectrics. Other types of ceramic dielectrics may be used, and various sorts of additives may be added.

Through repeated experiments, the inventors have realized that the amorphous dielectric film is sufficiently crystallized by hydrothermal treatment even at a low temperature of 300° C. or less. According to the embodiment of the invention, the amorphous dielectric film is hydrothermally treated at a temperature of 300° C. or less to obtain a crystalline dielectric film having a high dielectric constant of 30 or more without additional high-temperature thermal treatment.

Preferably, the hydrothermal treatment is carried out at a temperature of 80° C. to 300° C. More preferably, the hydrothermal treatment is carried out at a temperature of 150° C. to 300° C. The hydrothermal treatment performed at a temperature of less than 80° C. leads to slow crystallization of the amorphous dielectric film. Also, the hydrothermal treatment conducted at a temperature of more than 300° C. does not influence crystallization rate, but elevates pressure in the hydrothermal treatment apparatus, thus potentially increasing maintenance and repair costs thereof. To fabricate the crystalline TiO₂ film, the hydrothermal treatment is preferably conducted at a temperature of 150° C. to 250° C. To manufacture the crystalline PLZT film, the hydrothermal treatment is preferably carried out at a temperature of 200° C. to 300° C.

According to the embodiment of the invention, a method for manufacturing the amorphous dielectric film is applicable to the step S1 without special limits. For example, the amorphous dielectric sol is coated onto a substrate and baked to eliminate organic materials from the coated sol to manufacture the amorphous dielectric film. A variety of coating methods such as spin coating, deep coating and spray coating may be employed. Also, to obtain the dielectric film with a desired thickness, the coating and baking may be repeated for a number of times. The coating and baking are preferably performed at a temperature of 150° C. to 250° C. After the baking, the resultant structure is dried at a temperature of 150° C. to 250° C.

In another method to fabricate the amorphous dielectric film, deposition may be adopted. For example, the amorphous dielectric film may be deposited on the substrate via sputtering.

An explanation will be given hereunder regarding a method for manufacturing a crystalline dielectric film according to embodiments of the invention.

### EXAMPLE 1

In Example 1, a crystalline TiO₂ thin film was formed on a substrate via sol-gel spin coating and hyperthermal treatment. To do this, first, the substrate having a SiO₂ film, a Ti film and a Pt film sequentially stacked on an Si wafer was prepared. Then, an amorphous TiO₂ sol was coated onto the Pt/Ti/SiO₂/Si substrate via spin coating. The amorphous TiO₂ sol was obtained by hydrolyzing titanium alkoxide from alkoxy alcohol. For the titanium alkoxide, titanium isopropoxide was used. The spin coating was carried out at 4000 rpm for 20 seconds per one.

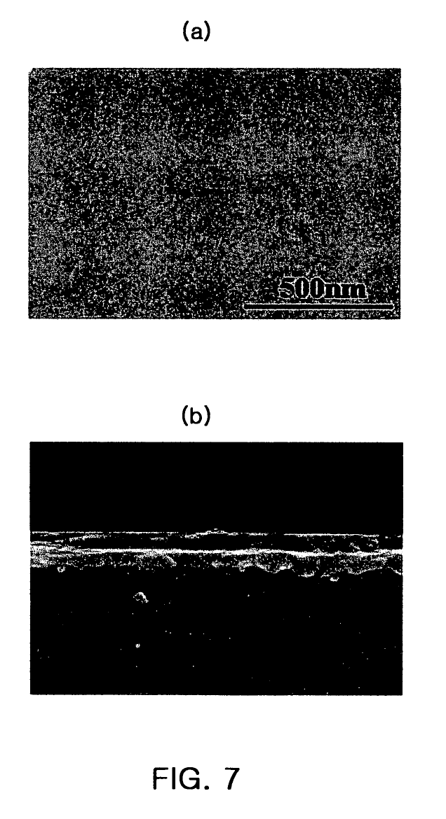

Thereafter, to eliminate organic material from the sol, the coated TiO₂ was baked at a temperature of 200° C. Such coating and baking were repeated three times. After the final baking, the baked resultant was heated at a temperature of 200° C. and dried. These processes allowed an amorphous TiO₂ film having a thickness of 300 nm to be formed on the Pt/Ti/SiO₂/Si substrate. FIGS. 7a and 7b are SEM pictures illustrating a surface and a cross-section of the TiO₂ film fabricated through the coating, baking and drying. As shown in FIGS. 7a and 7b, the TiO₂ film is in an amorphous state with no crystalline particles.

Thereafter, the amorphous TiO₂ film was hydrothermally treated at a temperature of 200° C. The hydrothermal treatment may be conducted via an autoclave-type hydrothermal treatment apparatus 10 as depicted in FIG. 10. Referring to FIG. 10, the hyrothermal treatment apparatus 10 includes a chamber 54 which provides a sealed space within an outer wall 50. In the chamber 54 are installed a container 56 having distilled water therein and a thermocouple 62 for measuring a temperature. A heater 52 is installed within the outer wall 50 and outside the chamber 54. To hydrothermally treat the amorphous TiO₂ film, the substrate S having the amorphous TiO₂ film formed thereon is immersed into the distilled water 58 within the sealed space, and then the chamber 54 was heated at an inside temperature of about 200° C.

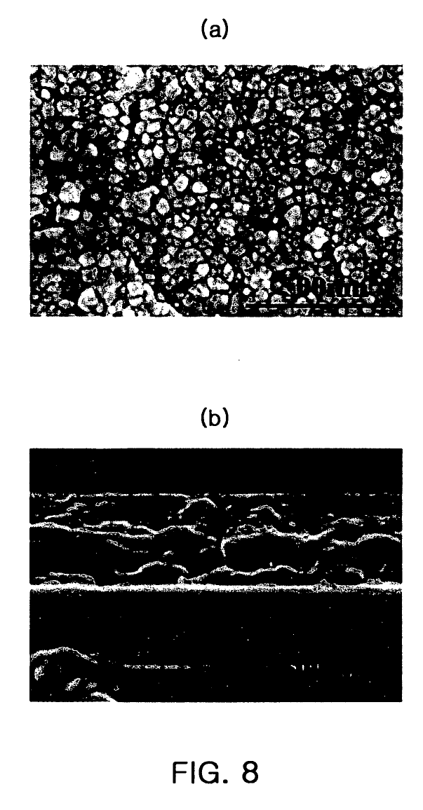

Such hydrothermal treatment changed the amorphous TiO₂ film into a crystalline TiO₂ film. The resultant crystalline TiO₂ thin film is illustrated in SEM pictures of FIGS. 8a and 8b. FIG. 8a depicts a surface of the crystal TiO₂ thin film manufactured according to Example 1 of the invention while FIG. 8b depicts a cross-section thereof. FIGS. 8a and 8b demonstrate a number of crystalline particles. This crystalline-state leads toga high dielectric constant of the TiO₂ film finally obtained according to this embodiment.

### EXAMPLE 2

In Example 2, a crystalline PLZT thin film was formed on a substrate via sol-gel spin coating and hydrothermal treatment. To do this, first, a Pt/Ti/SiO₂/Si substrate was prepared. Then an amorphous PLZT sol was coated onto the Pt/Ti/SiO₂/Si substrate via spin coating. The amorphous PLZT sol was obtained from methanol-based lead acetate trihydrate, titaniu isoprofoxid, lanthanum isopropoxide, and zirconium N-butoxide. The spin coating was conducted at 4000 rpm for 20 seconds per one.

Then, to eliminate organic material from the sol, the coated PLZT sol was baked at a temperature of 200° C. Such coating and baking were repeated three times. After the final baking process, the baked PLZT sol was heated to a temperature of 200° C. and dried. These processes allowed an amorphous PLZT thin film having a thickness of 300 nm to be formed on the Pt/Ti/SiO₂/Si substrate.

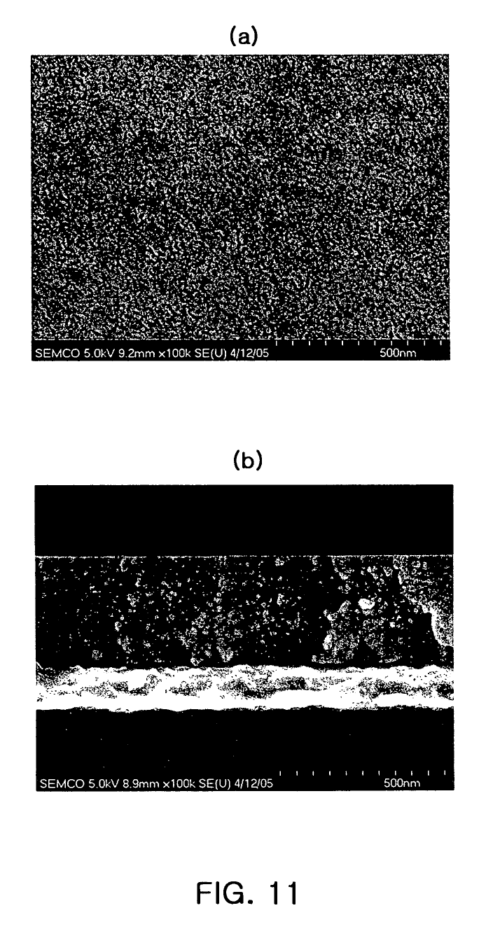

Thereafter, the amorphous PLZT thin film was hydrothermally treated at a temperature of 250° C. via the hydrothermal treatment apparatus 10 as shown in FIG. 10. This hydrothermal treatment changed the amorphous PLZT thin film into a crystalline PLZT thin film. The crystalline PLZT thin film obtained is illustrated in SEM pictures of FIGS. 11a and 11b. FIG. 11a depicts a surface of the crystalline PLZT thin film manufactured according to Example 2 of the invention and FIG. 11b depicts a cross-section thereof. SEM pictures of FIGS. 11a and 11b demonstrate a number of crystalline particles. This crystalline state leads to a high dielectric constant for the PLZT thin film finally obtained according to Example 2 of the invention.

FIGS. 3 to 6 are cross-sectional views for explaining a method for manufacturing a thin film capacitor according to an embodiment of the invention. First, referring to FIG. 3, for example, a metal film 103 is formed on a substrate 101 selected from a group consisting of a polymer-based PCB substrate, a silicon wafer substrate and a ceramic substrate. The metal film 103 constitutes a lower electrode of the capacitor. The metal layer 103 may be made of e.g., a Cu foil.

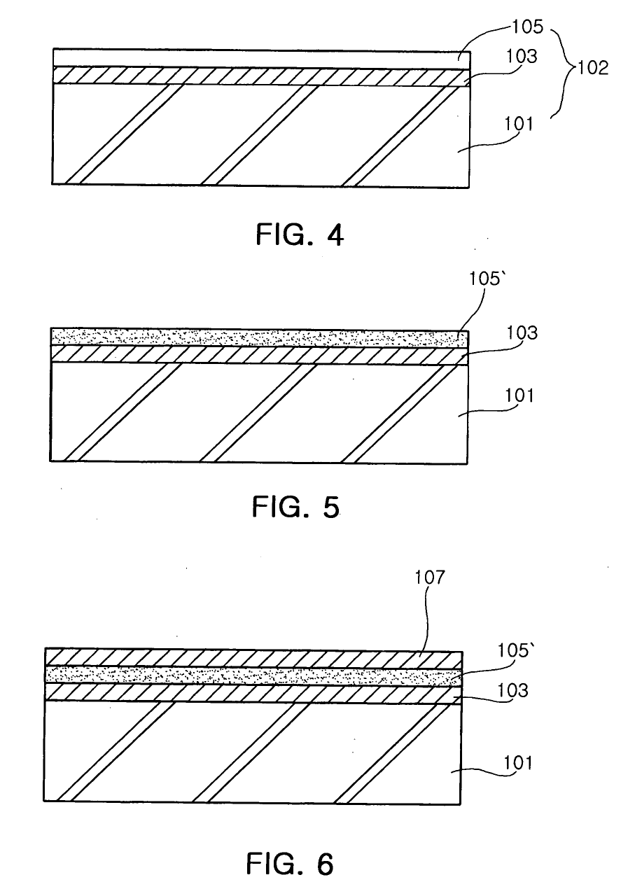

Next, as shown in FIG. 4, an amorphous dielectric film 105 is formed on the metal film 103. The amorphous dielectric film 105 may be formed by e.g., the method for forming the amorphous dielectric film as described in Examples 1 and 2 or sputtering.

Then, the resultant structure 102 is placed into the hydrothermal treatment apparatus 10 as shown in FIG. 10 and hydrothermally treated at a temperature of 80 to 300° C. This crystallizes the amorphous dielectric film 105, consequently producing a crystalline dielectric film 105′ as shown in FIG. 5. Thereafter, as shown in FIG. 6, a metal layer 107 is formed on the crystalline dielectric film 105′. This metal film 107 constitutes an upper electrode of the capacitor. As a result, the thin film capacitor is manufactured according to this embodiment of the invention. The thin film capacitor can be used beneficially as a thin film embedded capacitor.

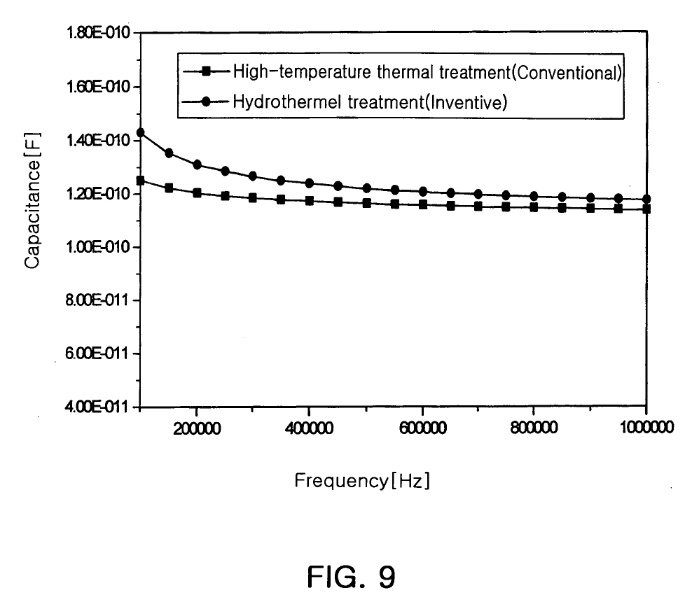

FIG. 9 is a graph illustrating capacitance in accordance with a frequency of the thin film capacitor manufactured. Especially, the capacitance of FIG. 9 denotes capacitance of a thin film capacitor having the crystalline TiO₂ thin film manufactured according to Example 1. As can be seen in FIG. 9, the thin film capacitor using the dielectric film manufactured according to the invention exhibits capacitance similar to or moderately higher than that of a conventional thin film capacitor using a dielectric film obtained by high-temperature thermal treatment. The thin film capacitors of the prior art and the invention used for measuring capacitance in FIG. 9 are of equal size and thickness, with TiO₂ adopted for dielectrics. In this fashion, the invention allows a high-quality crystalline dielectric film through a low temperature process of 300° C. or less and a thin film capacitor having sufficient capacitance.

As set forth above, according to the invention, an amorphous dielectric film can be crystallized easily by a low temperature process of 300° C. or less. This renders a substrate free from impairment which occurs during a high-temperature process and widens selection for the substrate materials. Therefore, even use of a heat-vulnerable polymer-based substrate enables a thin film embedded capacitor. In addition, the invention relatively simplifies a process and saves process costs and time.

While the present invention has been shown and described in connection with the preferred embodiments, it will be apparent to those skilled in the art that modifications and variations can be made without departing from the spirit and scope of the invention as defined by the appended claims.

1. A method for manufacturing a crystalline dielectric film comprising steps of:
forming an amorphous dielectric film on a substrate; and
hydrothermally treating the amorphous dielectric film by immersing into water.

2. The method according to claim 1, wherein the hydrothermal treating step comprises heating the amorphous dielectric film at a temperature of 300° C. or less in distilled water within a sealed space.

3. The method according to claim 1, wherein the hydrothermal treating step is carried out at a temperature of 80° C. to 300° C.

4. The method according to claim 1, wherein the hydrothermal treating step is carried out at a temperature of 150° C. to 300° C.

5. The method according to claim 1, wherein the amorphous dielectric film forming step comprises coating the amorphous dielectric sol onto a substrate and baking the coated amorphous dielectric sol.

6. The method according to claim 5, further comprising: drying the baked resultant after the baking step.

7. The method according to claim 5, wherein the coating step is carried out by spin coating, deep coating or spray coating.

8. The method according to claim 5, wherein the coating and baking are repeated for a number of times.

9. The method according to claim 1, wherein the amorphous dielectric film forming step comprises depositing the amorphous dielectric film on the substrate.

10. The method according to claim 9, wherein the amorphous dielectric film depositing step comprises sputtering the amorphous dielectric film onto the substrate.

11. The method according to claim 1, wherein the amorphous dielectric film forming step comprises forming an amorphous TiO₂ thin film on the substrate.

12. The method according to claim 11, wherein the amorphous TiO₂ film forming step comprises coating the amorphous TiO₂ sol onto the substrate and baking the coated amorphous TiO₂ sol.

13. The method according to claim 12, further comprising: drying the baked resultant, after the baking step.

14. The method according to claim 12, wherein the baking step is carried out at a temperature of 150° C. to 250° C.

15. The method according to claim 13, wherein the drying step is carried out at a temperature of 150° C. to 250° C.

16. The method according to claim 11, wherein the amorphous TiO₂ film forming step comprises depositing the amorphous TiO₂ thin film on the substrate.

17. The method according to claim 16, wherein the amorphous TiO₂ film depositing step comprises sputtering the TiO₂ thin film onto the substrate.

18. The method according to claim 11, wherein the hydrothermal treating step is carried out at a temperature of 150° C. to 250° C.

19. The method according to claim 1, wherein the amorphous dielectric film forming step comprises forming an amorphous PLZT thin film on the substrate.

20. The method according to claim 19, wherein the amorphous PLZT film forming step comprises coating a PLZT sol onto the substrate and baking the coated amorphous PLZT sol.

21. The method according to claim 20, further comprising: drying the baked resultant after the baking step.

22. The method according to claim 20, wherein the baking step is carried out at a temperature of 150° C. to 250° C.

23. The method according to claim 21, wherein the drying step is carried out at a temperature of 150° C. to 250° C.

24. The method according to claim 19, wherein the amorphous PLZT film forming step comprises depositing the amorphous PLZT film on the substrate.

25. The method according to claim 24, wherein the amorphous PLZT film depositing step comprises sputtering the amorphous PLZT thin film onto the substrate.

26. A crystalline dielectric film formed as described in claim 1.

27. A thin film capacitor comprising:
a lower electrode;
a crystalline dielectric film according to claim 26, formed on the lower electrode; and
an upper electrode formed on the crystalline dielectric film.

28. The thin film capacitor according to claim 27, comprising a thin film embedded capacitor.
